(19) United States
(12) Patent Application Publication
(10) Pub. No.: US 2006/0054212 A1
(43) Pub. Date: Mar. 16, 2006

(54) Solar photovoltaic mirror modules

(76) Inventors: Lewis M. Fraas, Issaquah, WA (US); Jany X. Fraas, Issaquah, WA (US); Han Xiang Huang, Issaquah, WA (US); James E. Avery, Issaquah, WA (US)

Correspondence Address: JAMES C. WRAY, 1493 CHAIN BRIDGE ROAD, SUITE 300, MCLEAN, VA, 22101, US

(21) Appl. No.: 11/223,803

(22) Filed: Sep. 9, 2005

Related U.S. Application Data
(60) Provisional application No. 60/608,517, filed on Sep. 10, 2004.

(51) Int. Cl. H01L 31/00

(52) U.S. Cl. 136/246; 136/259

(57) ABSTRACT

A planar concentrator solar power module has a planar base, an aligned array of linear photovoltaic cell circuits on the base and an array of linear Fresnel lenses or linear mirrors for directing focused solar radiation on the aligned array of linear photovoltaic cell circuits. The cell circuits are mounted on a back panel which may be a metal back plate. The module includes a voltage stand-off layer and heat spreader layer. The cell circuit array may include multiple sets of cells formed by dividing planar silicon cells. The cell circuit area is less than a total area of the module. Each linear lens or linear mirror has a length greater than a length of the adjacent cell circuit. The circuit backplate is encapsulated by lamination for weather protection. The planar module is generally rectangular with alternating rows of linear cell circuits and linear lenses or linear mirrors.

This application claims the benefit of U.S. Provisional Application No. 60/608,517 filed Sep. 10, 2004, which is incorporated herein by reference in its entirety.

Co-pending U.S. application Ser. No. 10/209,900, filed Aug. 2, 2002, which claims benefit of U.S. Provisional application No. 60/374,808 filed Apr. 24, 2002 and U.S. Provisional Application No. 60/391,122 filed Jun. 25, 2002, are all incorporated herein by reference in each of their entireties.

WO 2004/001859 A1 publication of PCT/US03/19524 is also incorporated herein by reference in its entirety.

### BACKGROUND OF THE INVENTION

Solar concentrators require very high investments to scale up production of a new concentrator cell. The investment required for manufacturing scale-up versions of a new cell is prohibitive. Another problem that needs to be solved is the cell-interconnect problem.

There is a need for a solar concentrator module that is a retrofit for a planar module and that is easier and cheaper to make. The business infrastructure for trackers and lenses should already be in-place. The heat load should be easily manageable. Investment requirements should be manageable and it should not threaten existing cell suppliers. Cells to be used should be available with very minor changes relative to planar cells. Therefore, low cost cells should be available from today's cell suppliers. Finally, it should be usable in early existing markets in order to allow early positive cash flow.

The demand for solar photovoltaic (PV) cells and modules has far outstripped PV cell supply.

### SUMMARY OF THE INVENTION

The present invention provides a 3-sun mirror module design that uses ⅓ the cells to triple module production at lower cost.

A problem for concentrated sunlight PV systems has been the requirement for investment in special cell and module manufacturing facilities. The new concentrator module uses existing planar cells. Standard 125 mm×125 mm SunPower A300 cells are cut into thirds. The new module design uses standard circuit laminant fabrication procedures and equipment. A thin aluminum sheet is added at the back of the laminant for heat spreading. While a standard planar module contains rows of 125 mm×125 mm cells, the new concentration modules have rows of one-third cells. Each row is 41.7 mm wide. Linear mirrors with triangular cross sections are located between the cell rows. The mirror facets deflect the sun's rays down to the cell rows. The result is a 3-sun concentrator module. Since mirrors are over ten times cheaper than expensive single crystal cell material, these 3-sun modules can be made at half the cost of today's solar PV modules.

These and further and other objects and features of the invention are apparent in the disclosure, which includes the above and ongoing written specification, with the claims and the drawings.

### BRIEF DESCRIPTION OF THE DRAWINGS

FIG. 1A is a perspective view of an assembled Planar Solar Cell Power Module.

FIG. 1B shows a cross section through the planar solar concentrator power module.

FIG. 1C shows a blow up section from FIG. 1B with a single lens and circuit element in more detail.

FIG. 2A shows a module with an exemplary laminar layer sequence

FIG. 2B shows a standard 1-sun module layer sequence.

FIG. 2C shows a mirror module layer sequence adding heat-spreader.

FIG. 2D shows standard 1-sun module laminant structure.

FIG. 2E shows a 3-sun module laminant structure.

FIG. 3A is a front view of a 1-sun cell.

FIG. 3B is a front view of a 1-sun cell cut into halves.

FIG. 3C is a back view of a 1-sun cell.

FIG. 3D is a back view of a 1-sun cell cut into thirds.

FIG. 4A is a back view of a triplet string with third cells.

FIG. 4B is a front view of the triplet string with third cells.

FIG. 5A is a front view of a laminant 4×9 cell array.

FIG. 5B is a back view of a laminant 4×9 cell array with an aluminum sheet heat spreader with slits or grooves.

FIG. 6A is an edge view of a mirror with two facets on each side.

FIG. 6B is a perspective view of the mirror shown in FIG. 6A.

FIG. 6C is an edge view of an end mirror.

FIG. 6D is a perspective view of the mirror shown in FIG. 6C.

FIG. 7A is a perspective view of a mirror array with end clips.

FIG. 7B is a perspective detail of the mirror array with end clips shown in FIG. 7A.

FIG. 7C is a front view of the mirror array shown in FIG. 7A.

FIG. 7D is an edge view of the mirror array with end clips shown in FIGS. 7A, 7B and 7C.

FIG. 8A is a front view of the mirror module with the one-third photovoltaic cells mounted between the mirrors.

FIG. 8B is an edge view of the mirror module shown in FIG. 8A.

FIG. 8C is a back view of the mirror module showing the aluminum sheet heat spreader.

FIG. 9 shows a perspective of the two-faceted mirrors used with the one-third cells in a power module.

FIG. 10 shows a top view of two planar cells wired in series.

FIG. 11 shows a top view of two planar cells cut in half and operated at 2× concentration using mirrors.

FIG. 12 shows an end view of the two planar cells cut in half and operated at 2× concentration using mirrors shown in FIG. 10.

### DETAILED DESCRIPTION OF THE PREFERRED EMBODIMENTS

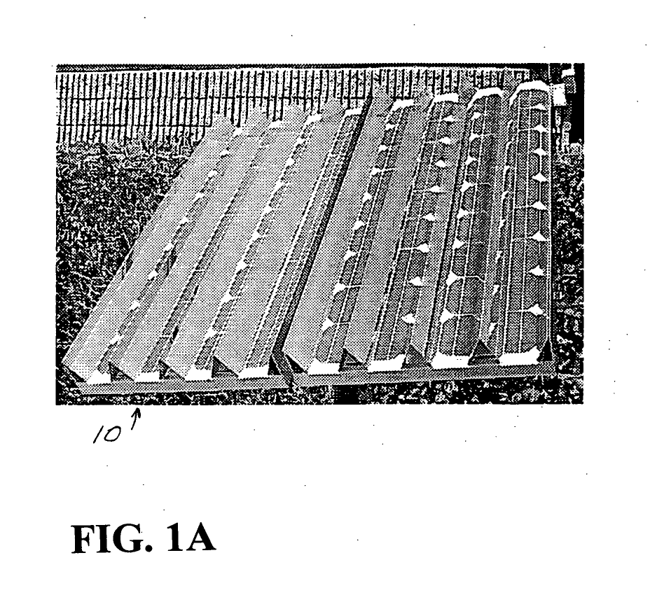

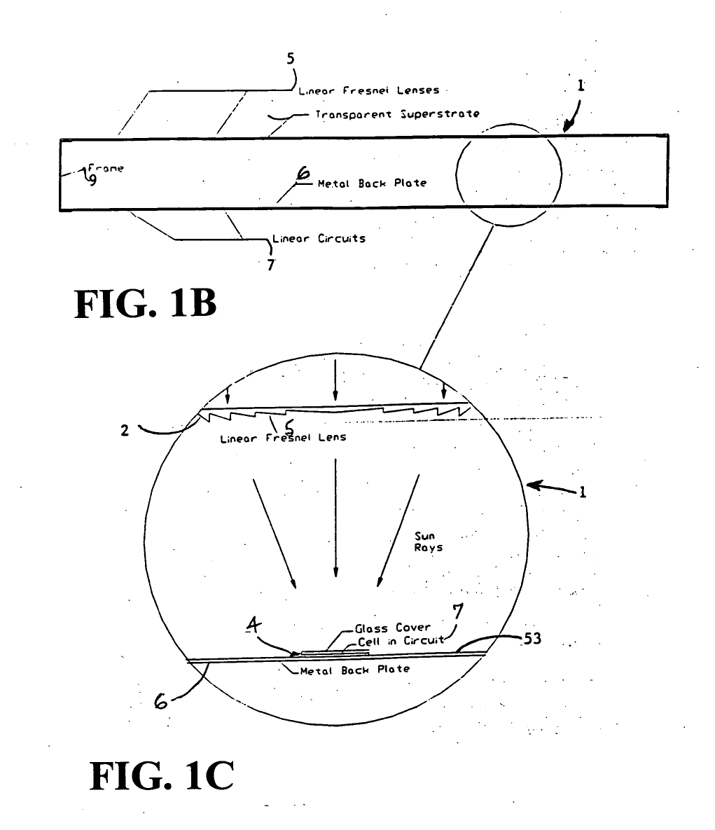

A photograph of the 2× mirror modules 10 is shown in FIG. 1A.

FIG. 1B shows a cross section through a planar solar concentrator power module 1. The cross section is perpendicular to the focal lines produced by the lenses and perpendicular to the circuit length dimension. FIG. 1C shows a blow up section from FIG. 1B showing a single lens 2 and circuit element 4 in more detail. The preferred planar concentrator solar module consists of a back panel of metal sheet 6 upon which linear silicon cell circuits 7 are mounted. In the exemplary embodiment depicted, for example, a metal frame 9, for example aluminum frame, surrounds the module 1 with the cells 4 of the cell circuits 7 mounted on the back panel 6. A lens array 3 of, for example, Fresnel lenses 5 is mounted on a glass front sheet 8 forming the front side of the planar concentrator solar module 1. The array 3 of linear Fresnel lenses 5 produces lines of focused solar radiation that fall on an aligned array of linear photovoltaic power circuits. Bus 53 is provided on an edge of the cell circuit.

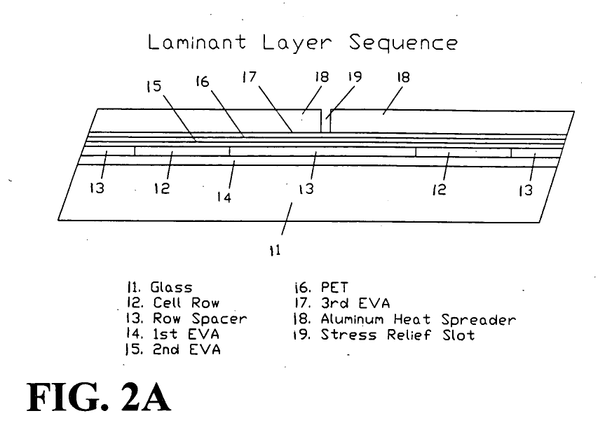

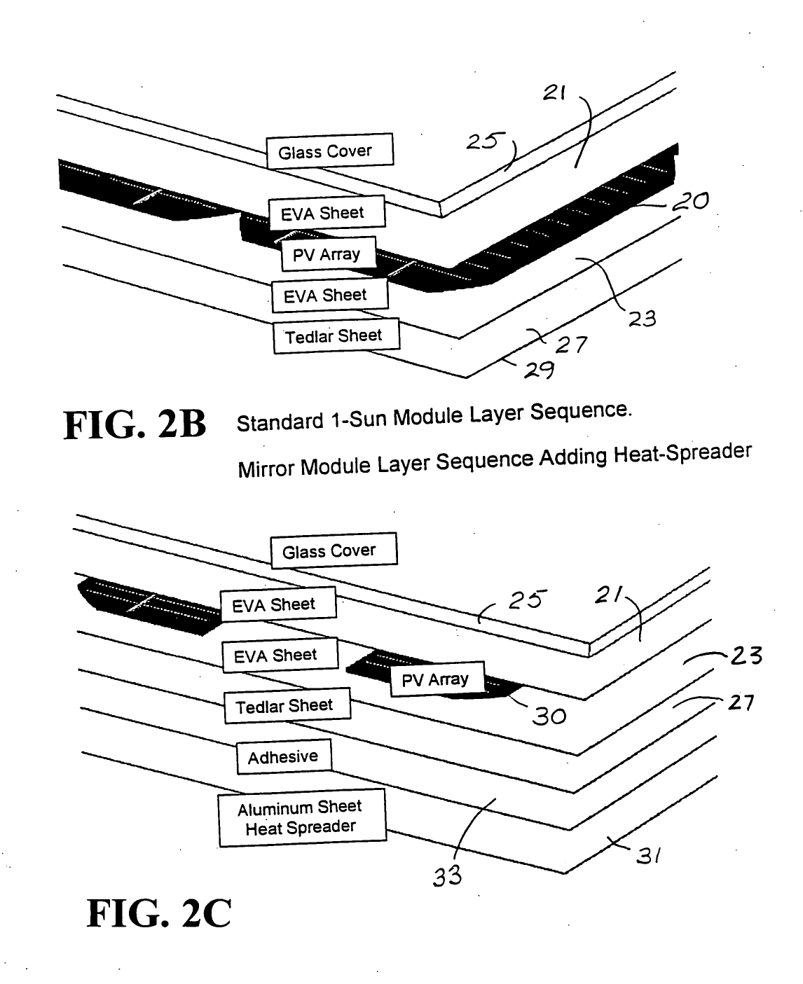

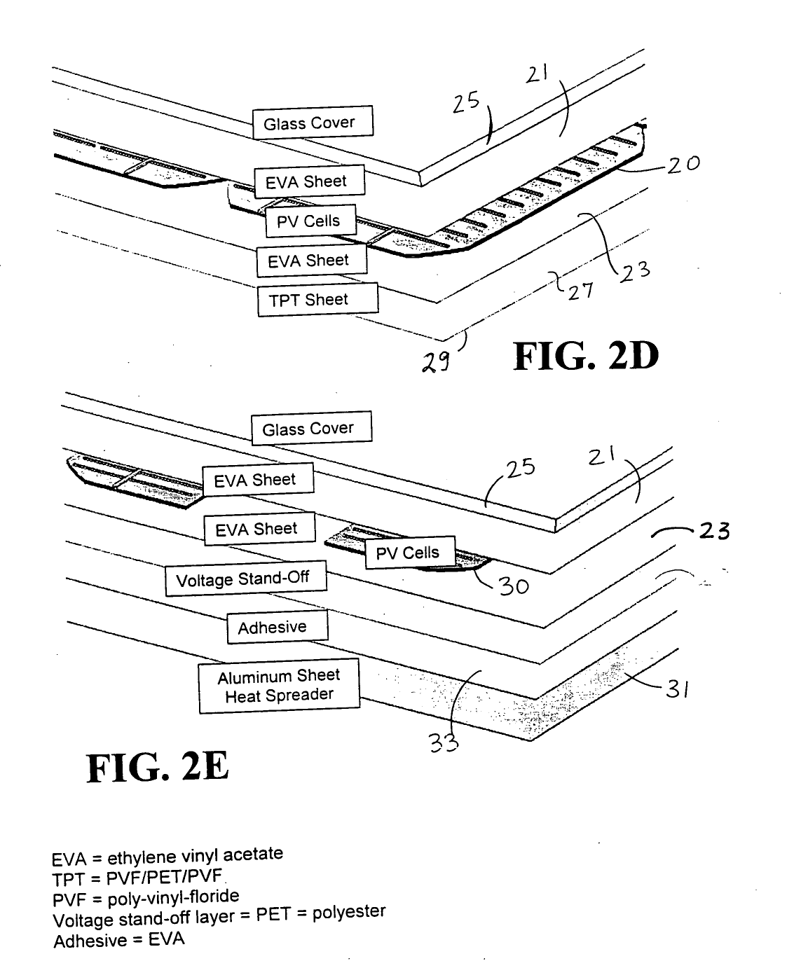

FIG. 2A shows an exemplary module 20 with a laminar layer sequence in which the layers may be sequentially arranged as follows: Glass substrate 11, first EVA 14, cell row(s) 12, row spacer 13, second EVA 15, PET 16, third EVA 17, metal layer 18 (for example, aluminum heat spreader), and stress relief slit/slot/groove 19.

FIGS. 2B and 2D show the layer sequence for a typical 1-sun module. Shown in FIGS. 2C and 2E is the addition of the heat spreader layer sequence employed when making the mirror modules.

FIGS. 2B and 2D show a standard 1-sun module layer sequence photovoltaic cell array 20 laminated between upper and lower EVA sheets 21, 23 with a glass cover layer 25 on the top and a Tedlar/TPT sheet layer 27 for a back 29.

FIGS. 2C and 2E show a mirror module layer sequence adding heat-spreader 31, with photo voltaic arrays 30 divided and laminated between upper and lower EVA sheets 21, 23 with a glass cover layer 25 on the top and a Tedlar sheet layer 27. A heat spreader layer 31, such as but not limited to aluminum sheet, is attached with, for example, an adhesive layer 33 to the Tedlar/TPT sheet layer 27.

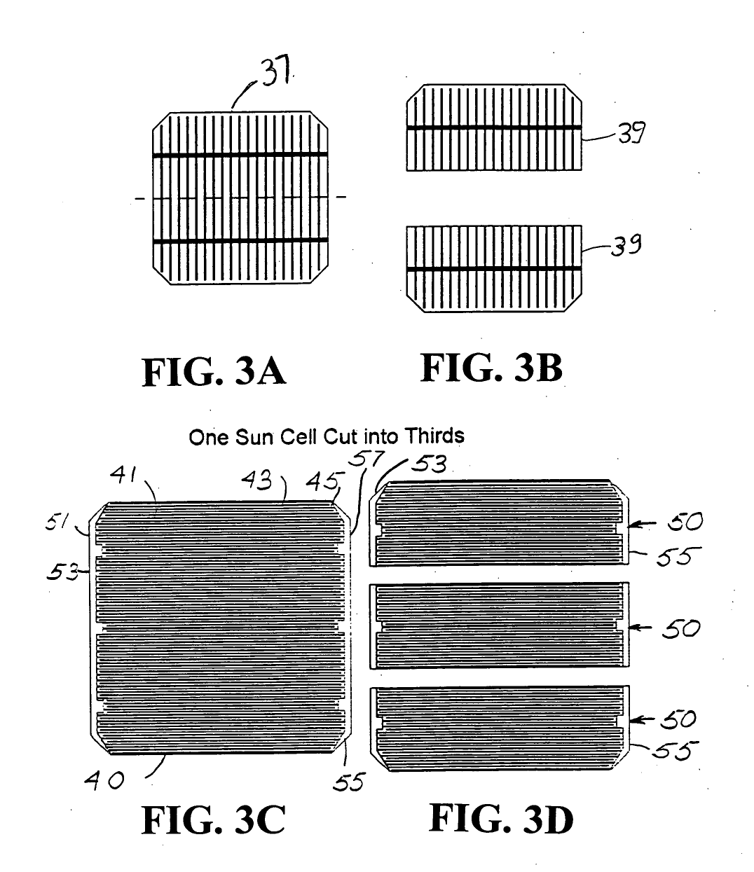

FIG. 3A is a back view of a 1-sun cell 37. FIG. 3B is a back view of a 1-sun cell cut into halves 39.

The exemplary 3× mirror-module is described herein. FIGS. 3C through 8C describe this 3× embodiment in detail. This 3× embodiment reduces the module cost by reducing further the amount of single-crystal silicon cell material required.

Recently, SunPower Corp has started to manufacture a new type of 1-sun cell. That cell 40 is shown in FIG. 3C. Its metal grid 41 differs from earlier designs. This SunPower cell has both n and p collection grids 43, 45 on its back 47. The n grid lines 43 run to an n bus 53 on one cell edge 51. The p grid lines 45 run to a p bus 55 on the opposite edge 57. Cutting those cells into thirds 50 is shown in FIG. 3D.

Both sets of grid lines 43, 45 are plated to a thickness that allows good current flow even at 3-sun current levels. That has been demonstrated via measurements with the following favorable results.
Suns=2.998; Isc=5.755 A; Voc=0.703 V; FF=0.717; Pmax=2.9 W
Efficiency=19.46%.

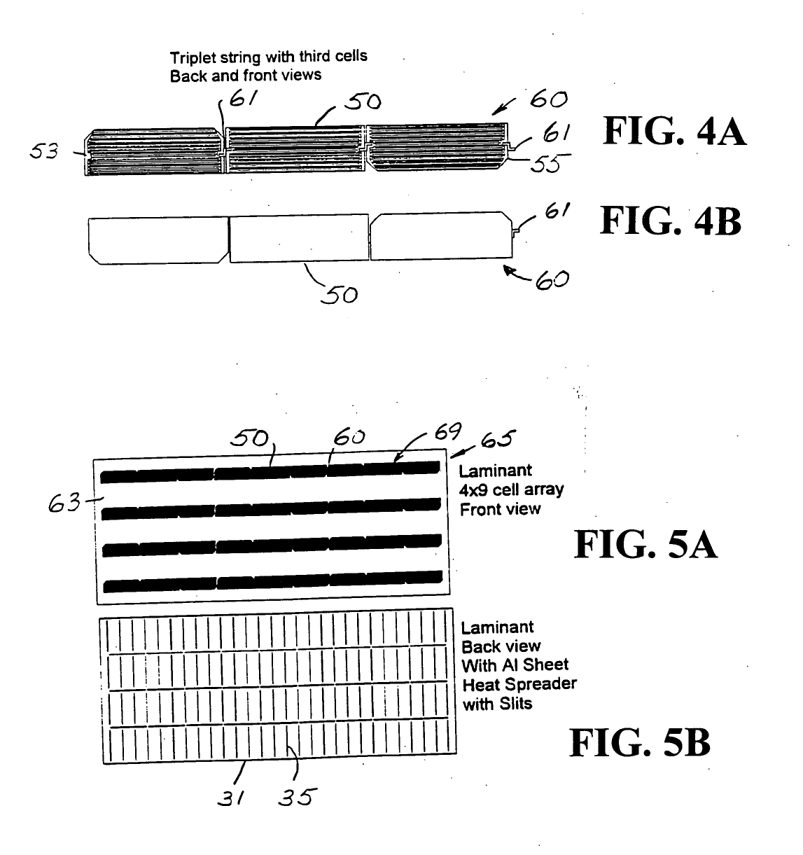

The one-third cells 50 are series connected 60 with connectors 61 between busses 53, 55 as shown in FIGS. 4A and B. Then the series connected cells 50 are laminated 63 into circuit assembles 65 as shown in FIG. 5A using the layer sequence shown in FIG. 2B and incorporating the metal heat spreader 31 on the circuit backside 29. An important detail to note in FIG. 5B is that the 0.5 mm to 0.75 mm thick aluminum sheet heat spreader 31 has stress relief slits or grooves 35 to accommodate the difference in thermal expansion coefficient between the heat spreader sheet 31 and the other silicon and glass laminant materials shown in FIGS. 2A and 2B. The slits or grooves 35 run from the cells 50 toward the mirrors so as not to interfere with the heat flow direction.

We also note that the stress relief slits 35 can be discontinuous as shown in FIG. 5B such that the heat spreader sheet 31 remains as one large sheet or, alternatively, the stress relief slits can be continuous such that that heat spreader then consists of smaller rectangular tiles arranged in a pattern to form the heat spreader sheet 31.

FIG. 5A shows a thirty-six cell circuit 65 with four rows 69 containing nine cells 50 each. The cells are approximately 5″ long each. This particular module has dimensions of approximately 20″ by 47″, preferably 21″ by 47″, and represents one of the popular sizes for 1-sun planar modules. Another popular size might contain seventy-two cells 50 with six rows 69 of twelve cells 50 each and have dimensions of approximately 30″ by 62″, preferably 31″ by 62″. Alternatively, there can be twelve rows 69 of six cells 50. A large number of size variations are possible.

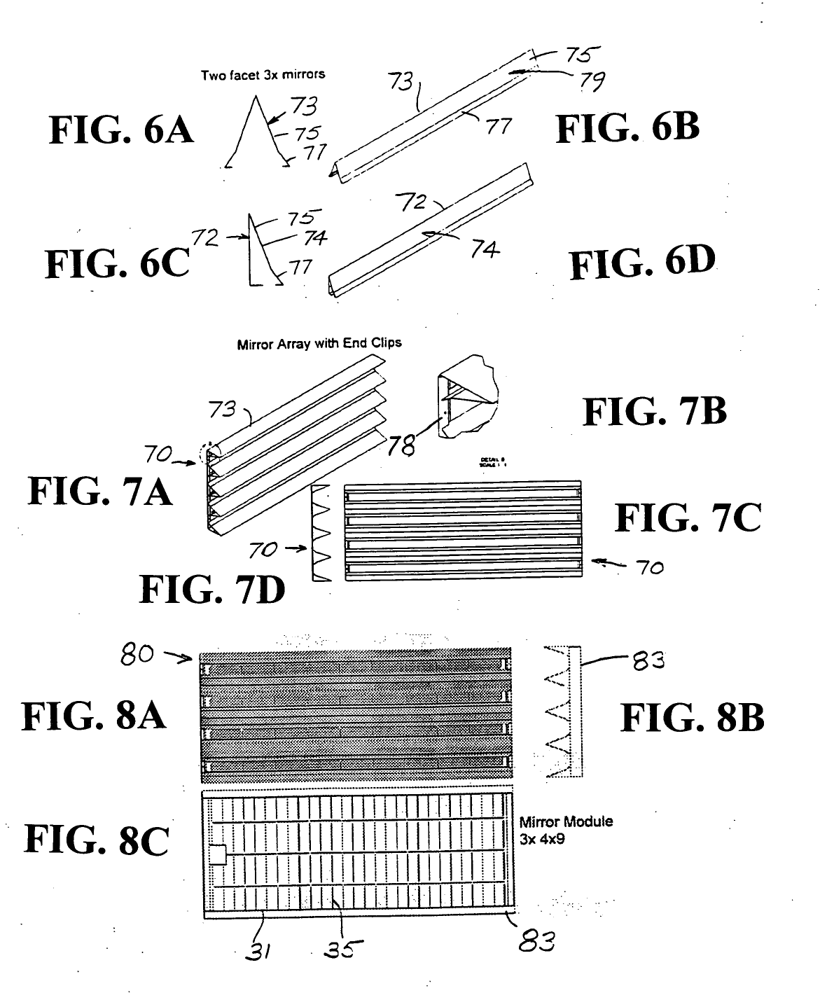

FIGS. 6A-D show the mirror constructions 71 for the 3× module 80. Note that in contrast to the 2× design, these mirrors 73 have two facets 75, 77 per face 79. The end mirrors 72 shown in FIGS. 6C and D have only one face 74 with two facets 75 and 77. The mirrors can be folded sheet metal, silvered glass mounted onto plastic extrusions, or silvered tape coatings rolled onto aluminum sheets prior to bending into the proper shapes. Several different mirror types and coatings are viable.

The mirrors 73 are then tied together in an array 70 using end clips 78 as shown in FIGS. 7A-D. Finally, the mirror array 70 is screwed down onto a metal frame 83 that surrounds the laminated circuit as shown in FIGS. 8A-D, completing the 3× mirror module. This feature allows for mirror replacement if required over time.

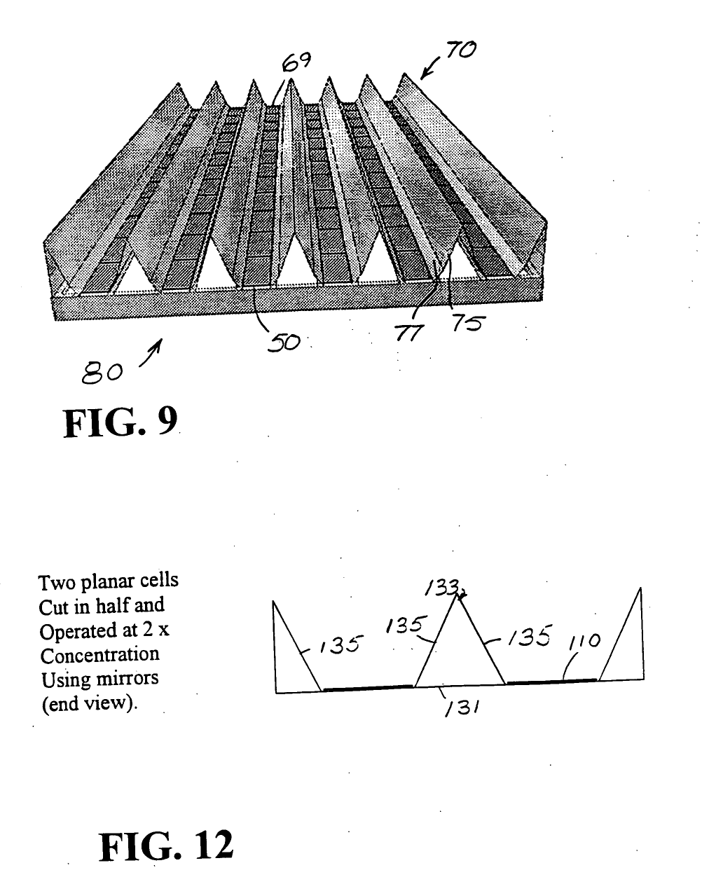

The planar solar concentrator power module array 80 shown in FIG. 9 replaces expensive single crystal cell areas with inexpensive mirror areas to reduce the cost of solar generated electricity.

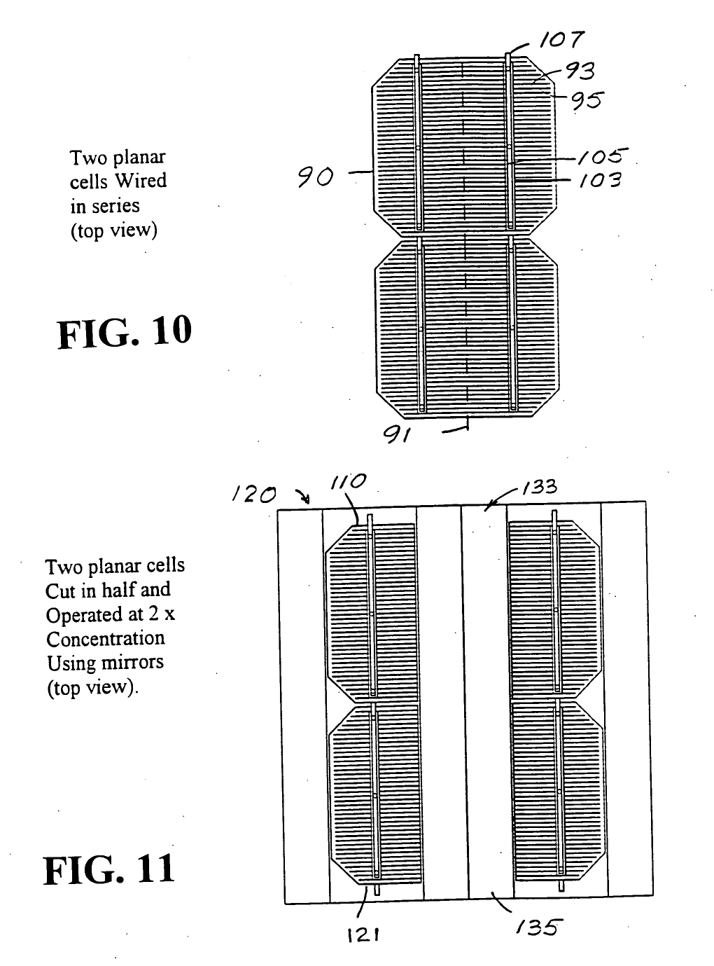

FIG. 9 shows a power module 80 bearing an array 70 of two-faceted linear mirrors with generally triangular cross sections located between the cell rows 69. The mirror facets 75, 77 deflect the sun's rays down to the rows 69 of one-third cells 50. An embodiment is shown in FIGS. 10, 11, and 12.

FIG. 10 shows two series connected planar photovoltaic cells 90 which can be centrally divided along line 91. The grid lines 93 and 95 are connected to busses 103, 105, and the busses are connected in series by extended connectors 107 cutting the cells 90 along line 91 forms the series-connected planar half cells 110 shown in FIG. 11. FIG. 11 shows a solar concentrator power module 120 consisting of rows 121 of half solar cells 110 separated by rows 133 of mirrors 135. The mirrors deflect sunlight down to the cells. The cells are mounted on a metal sheet heat spreader 131. The cell and mirror array sunlight-collection-area is the same as the heat spreader sheet area. As shown in FIG. 12 the heat spreader 131 moves heat from under the cells 110 to the area underneath the mirrors 135 for uniform heat removal by contact with air.

FIG. 10 shows typical 1-sun silicon cells 90 available in high volume production today. The cell shown has a metal collection grid on its front side with grid lines 93, 95 connected to two current busing lines 103,105. In one embodiment of the planar solar concentrator power module depicted in FIG. 11, the cells 90 are cut in half. Current busing lines 103,105 remain on each half as shown in FIG. 11. The half-cells 110 are separated by intermediate rows 133 of mirrors 135 as shown in FIGS. 11 and 12. The result is a 2× mirror-module 120 with double the power output for the same amount of silicon cell area shown in FIG. 10. A perspective view of the assembly of FIG. 12 is shown in FIG. 10. Preferably, the width of the row spacer sets the cell row spacing equal to the mirror spacing which is set by the slots/grooves in the end clip. The cell row spacer sets the width between cells equal to the width between mirrors to within a tolerance of about±2 mm.

Some specific features of the product include stress relief slits or grooves 35 in heat spreader sheet 31, multi faceted mirrors 73, replaceable mirrors 73, SunPower cell segments 50, and 3× module design 80.

This invention describes a solar photovoltaic module preferably for use on earth, though other uses are within the scope of this invention. This new photovoltaic module consists of a large weather proofed laminated PV-cell circuit containing periodic alternating rows of cells separated by row spacers. Said laminated circuit has a thin metal heat spreader on its backside for heat removal to the ambient air. An edge frame surrounds said laminated circuit and supports an array of linear concentrating elements above said laminated circuit. The laminated circuit and the linear sunlight concentrating elements are aligned such that sunlight is directed to the linear cell rows in the laminated circuit.

The object of this invention is a dramatically lower cost photovoltaic module than today's most prevalent 1-sun solar photovoltaic module. Relative to today's PV modules, the invention includes three changes to accomplish this objective.

The first step in accomplishing this low cost objective is to use the same silicon single crystal or cast multi-crystalline cells that are in high volume production today. These cells are simply cut into halves as shown in FIG. 3A-3B or thirds as shown in FIGS. 3C-3D, or fourths, etc., as is evidently possible from FIG. 3A allowing use of one-half, one-third, etc., as much of the expensive cell material in our new module.

The second key to our cost reduction strategy is to use the existing low-cost terrestrial module lamination process because it yields modules with proven durability. This produces cell-circuits that are dramatically different than those used on space satellites. There is typically a large glass plate on top of the laminated circuit that can be as large as 1.5 square meters and much too thick and heavy for use in space. It prevents corrosion of the circuit in the wet terrestrial environment.

Starting with this low-cost terrestrial lamination concept, we then make some important changes in this lamination as shown in FIGS. 2A, 2B, and 2C. FIG. 2B shows the standard 1-sun laminated circuit and FIGS. 2A and 2C show the three changes we make for our new laminated circuit. Our first change is to use rows of half-cells or third-cells, etc., with row spacers (FIG. 2A) between the rows to set repeatable well-defined spaces between the rows.

As we plan to concentrate the solar energy onto the cell rows, our second change is to add a thin metal heat spreader to the backside of the laminated circuit as shown in FIGS. 2A and 2C. This metal sheet spreads the heat uniformly for air cooling from the backside of said laminated circuit. Since laminations are done with flat parts, finned heat sinks are not appropriate or necessary. A flat sheet heat spreader is sufficient for the low solar concentrations described here.

The third change is to use thinner insulating layers between the back of the cells and the metal heat spreader while still maintaining the required voltage standoff. Experimentation has shown that these changes in the lamination are non-trivial. For example, because the aluminum sheet thermal expansion coefficient is much larger than that of the glass-cover plate, we found that the laminated circuit will bow unless we add stress relief slots in the aluminum sheet as shown in FIG. 2A. However, given these stress relief slots, we have now shown that our new laminated circuits pass the standard terrestrial qualification tests that include survival through large numbers of thermal cycles.

Given the new laminated circuit as described, various low cost linear solar concentrating elements can be used. This is the third key to our low cost module strategy since these concentrating elements are much cheaper than the solar cell material we have saved in the fabrication of our new laminated circuit. These concentrating elements can include either a linear Fresnel lens array or linear mirror funnels as shown in the figures.

While the invention has been described with respect to specific embodiments, modifications and variations of the invention may be constructed without departing from the scope of the invention, which is described in the following claims.

We claim:

1. A solar concentrator module comprising a heat spreader layer, upper and lower adhesive layers, photovoltaic cell array layer laminated between the upper and lower adhesive layers, a cover layer and a voltage stand off layer.

2. The apparatus of claim 1, wherein the photovoltaic cell array is divided and laminated between the upper and lower layers.

3. The apparatus of claim 2, further comprising stress relief slots or grooves in the heat spreader layer.

4. The apparatus of claim 3, wherein the heat spreader layer is an aluminum sheet adhesive bonded to the voltage stand off layer.

5. The apparatus of claim 4, wherein the photovoltaic cell array comprises cells derived by dividing commercial planar silicon cells into equal sized smaller parts.

6. The apparatus of claim 1, wherein the cover layer is glass.

7. The apparatus of claim 1, wherein the voltage stand off layer is a polyester sheet.

8. The apparatus of claim 1, further comprising rows of cells with metal grids including n and p collection grids on a back side.

9. The apparatus of claim 8, further comprising cells with n grid lines running to an n bus on one cell edge and p grid lines running to a p bus on an opposite cell edge.

10. The apparatus of claim 9, wherein both grid line types are plated to a thickness thereby allowing for good current flow.

11. The apparatus of claim 5, wherein the divided cells are series connected in rows with connectors between busses.

12. The apparatus of claim 11, wherein the series connected cells are laminated into a circuit assembly.

13. The apparatus of claim 12, wherein the heat spreader layer is laminated on a backside of the circuit assembly.

14. The apparatus of claim 13, wherein the stress relief slits or grooves accommodate differences in thermal expansion coefficient between the heat spreader layer and adjacent layers.

15. The apparatus of claim 14, further comprising mirrors mounted between the cell rows, wherein the slits or grooves run from the cells toward the mirrors mounted between the cell rows to avoid interference with heat flow directions.

16. The apparatus of claim 13, wherein the circuit assembly comprises thirty-six cell circuits in a four by nine cell array.

17. The apparatus of claim 16, wherein the cells are approximately 5″ long each.

18. The apparatus of claim 17, wherein the module has dimensions of approximately 21″ by 47″.

19. The apparatus of claim 13, wherein the circuit assembly comprises seventy-two cells in a six by twelve cell array.

20. The apparatus of claim 19, wherein the module has dimensions of approximately 31″ by 62″.

21. The apparatus of claim 11, further comprising mirrors mounted on the module.

22. The apparatus of claim 21, wherein the mirrors comprise two facets per face of each mirror.

23. The apparatus of claim 22, wherein end mirrors comprise a face with two facets.

24. The apparatus of claim 21, wherein the mirrors are selected from the group consisting of coatings, sheet metal, silvered glass mounted onto plastic extrusions, silvered tape coatings rolled onto aluminum sheets prior to bending into proper shapes, and combinations thereof.

25. The apparatus of claim 21, wherein the mirrors are then tied together in an array with end clips wherein the mirrors fit into slots in the end clips with the slots setting the mirror spacing reproducibly.

26. The apparatus of claim 25, further comprising a metal frame surrounding the laminated circuit, wherein the mirror array is coupled to the metal frame to form a sunlight concentrating mirror module.

27. The apparatus of claim 25, wherein the mirror array replaces single crystal cell areas.

28. The apparatus of claim 25, wherein an array of linear mirrors with generally triangular cross sections are located between the cell rows and wherein the mirror facets deflect sun rays down to the rows of the divided cells.

29. The apparatus of claim 28, further comprising cell rows with plastic sheet spacers between the cell rows to reproducibly fix row spacings.

30. The apparatus of claim 5, wherein the divided cells are derived by cutting planar silicon cells into thirds.

31. The apparatus of claim 5, wherein the divided cells are derived by cutting planar silicon cells into halves, wherein the module comprises rows of half solar cells separated by rows of mirrors, and wherein the mirrors deflect sunlight down to the cells.

32. The apparatus of claim 28, wherein the cells are mounted on a metal sheet heat spreader.

33. The apparatus of claim 32, wherein the cell and mirror array sunlight-collection-area is same as the heat spreader sheet area.

34. The apparatus of claim 33, wherein the heat spreader sheet moves heat from under the cells to areas underneath the mirrors for uniform heat removal by contact with air.

35. The apparatus of claim 31, wherein the planar silicon cells divided in half have a metal collection grid on a front side with grid lines connected to two current busing lines.

36. The apparatus of claim 35, wherein the cells are cut in half and wherein current busing lines remain on each half.

37. The apparatus of claim 36, wherein the half-cells are separated by intermediate rows of mirrors.

38. The apparatus of claim 37, wherein the module is a sunlight concentrating mirror-module.

39. The apparatus of claim 29, wherein a width of the row spacer sets a cell row spacing equal to a mirror spacing set by the slots in the end clip to within about+/−2 mm.

40. The apparatus of claim 21, wherein the module comprises layers selected from the group consisting of glass substrate layers, polymer layers, layers of series connected cell rows of divided cells, row spacers, voltage standoff layers, adhesive layers, heat spreader layers, and combinations thereof.

41. The apparatus of claim 21, wherein the module comprises sequentially glass substrate layer, first polymer layer, layer of series connected rows of divided cells, row spacer, second polymer layer, voltage stand off layer, adhesive layer, heat spreader layer, and further comprising stress relief slots or grooves.

42. A solar power module apparatus comprising a circuit assembly, photovoltaic cell array layer in the circuit assembly, and linear mirrors in the circuit assembly for deflecting sun rays to the rows of solar cells.

43. The apparatus of claim 42, wherein the circuit assembly comprises linear extrusions.

44. The apparatus of claim 43, wherein the linear extrusions include side wall extrusions disposed along boundaries of the circuit assembly.

45. The apparatus of claim 44, wherein the circuit assembly further comprises inner mirrors having triangular cross-sections.

46. The apparatus of claim 45, further comprising a back panel in the circuit assembly.

47. The apparatus of claim 46, wherein the back panel is a metal sheet.

48. The apparatus of claim 47, wherein the photovoltaic cell array layer comprises rows of series connected solar cells derived from divided commercial planar silicon cells comprising parts of equal size mounted on the metal sheet.

49. The apparatus of claim 48, further comprising a metal frame and end plates surrounding the circuit assembly.

50. The apparatus of claim 48, wherein an area of the cells is less than a total area of the module.

51. The apparatus of claim 49, wherein the mirrors are disposed between rows of the linear silicon-cell circuits.

52. The apparatus of claim 51, further comprising linear extrusions on the circuit assembly, and wherein the mirrors are mounted on faces of the linear extrusions for deflecting sun rays impinging on each mirror onto the linear silicon-cell circuits.

53. The apparatus of claim 52, wherein the linear extrusions include side-wall extrusions.

54. The apparatus of claim 52, wherein the linear extrusions include inner extrusions with triangular cross-sections.

55. The apparatus of claim 53, further comprising slots in the side wall extrusions, wherein the back panel is coupled to the slots in the side wall extrusions.

56. The apparatus of claim 52, further comprising end to end fastener openings in the linear extrusions and fasteners disposed in the fastener openings for coupling the circuit assembly, the linear mirrors on the linear extrusions, the back panel and the end plates.

57. The apparatus of claim 56, further comprising a heat spreader layer.

58. The apparatus of claim 57, further comprising a voltage stand off layer.

59. The apparatus of claim 58, wherein the heat spreader layer is an aluminum sheet bonded to the voltage stand off layer.

60. The apparatus of claim 59, wherein the voltage stand off layer is a polyester sheet.

61. The apparatus of claim 42, further comprising a transparent cover.

62. The apparatus of claim 58, wherein the transparent cover is a glass plate.

63. The apparatus of claim 58, further comprising slots or grooves in the heat spreader layer.

64. The apparatus of claim 63, wherein the slots or grooves are stress relief devices that accommodate differences in thermal expansion coefficient between the heat spreader layer and adjacent layers.

65. A method of assembling a planar concentrator solar power module comprising dividing commercial planar photovoltaic cells into smaller parts of equal size, mounting the divided cells on a heat spreader plate and forming a circuit element, bonding the heat spreader plate to a voltage stand off sheet, connecting the cells in series to form linear circuit rows, mounting linear mirrors on the plate, alternating the linear circuit rows and the linear mirrors in the circuit element, deflecting sun rays with the linear mirrors on to the linear circuit rows, concentrating solar energy into the linear circuit rows and providing optimal thermal energy management.

66. The method of claim 65, further comprising transferring waste heat generated from the concentrating solar energy to the heat spreader plate, spreading the waste heat laterally through the heat spreader plate and causing a temperature of the heat spreader plate to be uniform.

67. The method of claim 65, wherein the mounting the cells on the heat spreader plate comprises providing slots or grooves between alternating circuits and allowing a temperature of the heat spreader plate to be uniform.

68. The method of claim 65, further comprising mounting linear extrusions as a frame around the heat spreader plate and mounting the linear mirrors to the linear extrusions and mounting the linear circuit rows between the mirrors.

69. The method of claim 68, further comprising allowing for optimal seasonal alignment by providing linear mirrors longer than the linear circuit rows, aligning the mirror focal line in a north/south direction and giving a tracking tolerance in north/south direction corresponding to a movement of the sun.

70. A concentrator solar power module apparatus comprising a planar heat spreader base, an aligned array of linear photovoltaic cell circuits of divided cells of equal size derived from commercial planar silicon cells on the heat spreader base, an aligned array of linear concentrator elements for directing solar radiation on the aligned array of linear photovoltaic cell circuits, the linear photovoltaic circuits being in thermal contact with the heat spreader base and being electrically isolated from the heat spreader base, wherein an area of the heat spreader base is equal to a total module area for efficient heat spreading and heat removal.
